(19) United States
(12) Patent Application Publication
(10) Pub. No.: US 2016/0284911 A1
(43) Pub. Date: Sep. 29, 2016

(54) PHOTOVOLTAIC CELL

(71) Applicant: Panasonic Intellectual Property Management Co., Ltd., Osaka (JP)

(72) Inventors: Kouki ICHIHASHI, Osaka (JP); Tohru NAKAGAWA, Shiga (JP); Nobuhiko HAYASHI, Osaka (JP); Norio KIRITA, Wakayama (JP)

(21) Appl. No.: 15/070,428

(22) Filed: Mar. 15, 2016

(30) Foreign Application Priority Data
Mar. 23, 2015 (JP) 2015-059015
Jan. 8, 2016 (JP) 2016-002211

(51) Int. Cl. H01L 31/054

(52) U.S. Cl. CPC H01L 31/0543; H01L 31/0547

(57) ABSTRACT

A photovoltaic cell according to the present disclosure includes: a light-receiving lens having condensing function; a light guide element disposed at an emission surface side of the light-receiving lens; a translucent glass substrate mounted to be in contact with an emission surface of the light guide element; and a photoelectric conversion element which is disposed at a position opposite the light guide element and on which light emitted from the glass substrate is incident. The light-receiving lens is configured such that an incidence surface is a convex surface and an emission surface is formed into a Fresnel shape having positive optical power.

### BACKGROUND

1. Technical Field

The present disclosure relates to a photovoltaic cell used for photovoltaic power generation.

2. Description of Related Art

A concentrating photovoltaic cell including an optical element having an integral structure in which a condenser lens and a photovoltaic cell are integrated is disclosed in International Publication No. 2012/160994 (hereinafter referred to as “Patent Literature 1”). This configuration aims to enhance an output by efficiently condensing sunlight to elements constituting the photovoltaic cell.

### SUMMARY

A photovoltaic cell according to the present disclosure includes: a light-receiving lens having condensing function; a light guide element disposed at an emission surface side of the light-receiving lens; a translucent substrate mounted to be in contact with an emission surface of the light guide element; and a photoelectric conversion element which is disposed at a position opposite the light guide element and on which light emitted from the substrate is incident. The light-receiving lens is configured such that an incidence surface is a convex surface and an emission surface is formed into a Fresnel shape having positive optical power.

### BRIEF DESCRIPTION OF DRAWINGS

FIG. 1 is a schematic sectional view illustrating a configuration of a photovoltaic cell according to an exemplary embodiment of the present disclosure;

FIG. 2 is a sectional view for describing an optical path of sunlight incident on the photovoltaic cell according to the exemplary embodiment;

FIG. 3 is a sectional view illustrating optical paths of a short-wavelength light beam and a long-wavelength light beam which are incident on a light guide element according to the exemplary embodiment;

FIG. 4 is a sectional view illustrating optical paths of a short-wavelength light beam and a long-wavelength light beam which are incident on a light guide element including only a light guide part; and

FIG. 5 is a graph illustrating a relationship between a photoelectric conversion wavelength band of a photoelectric conversion element and a focal length according to the exemplary embodiment.

### DETAILED DESCRIPTION

### Exemplary Embodiment

Hereinafter, an exemplary embodiment will be described in detail with reference to the accompanying drawings. It is noted, however, that descriptions in more detail than necessary will sometimes be omitted. For example, detailed descriptions of well-known items and duplicate descriptions of substantially the same configuration will sometimes be omitted. This is to avoid unnecessary redundancy in the following description and to facilitate understanding by those skilled in the art.

Note that the accompanying drawings and the following descriptions are provided so as to facilitate full understanding of the present disclosure by those skilled in the art, and these are not intended to limit the subject matter defined by the claims

### Exemplary Embodiment

[1. Configuration]

[1-1. Overall Configuration]

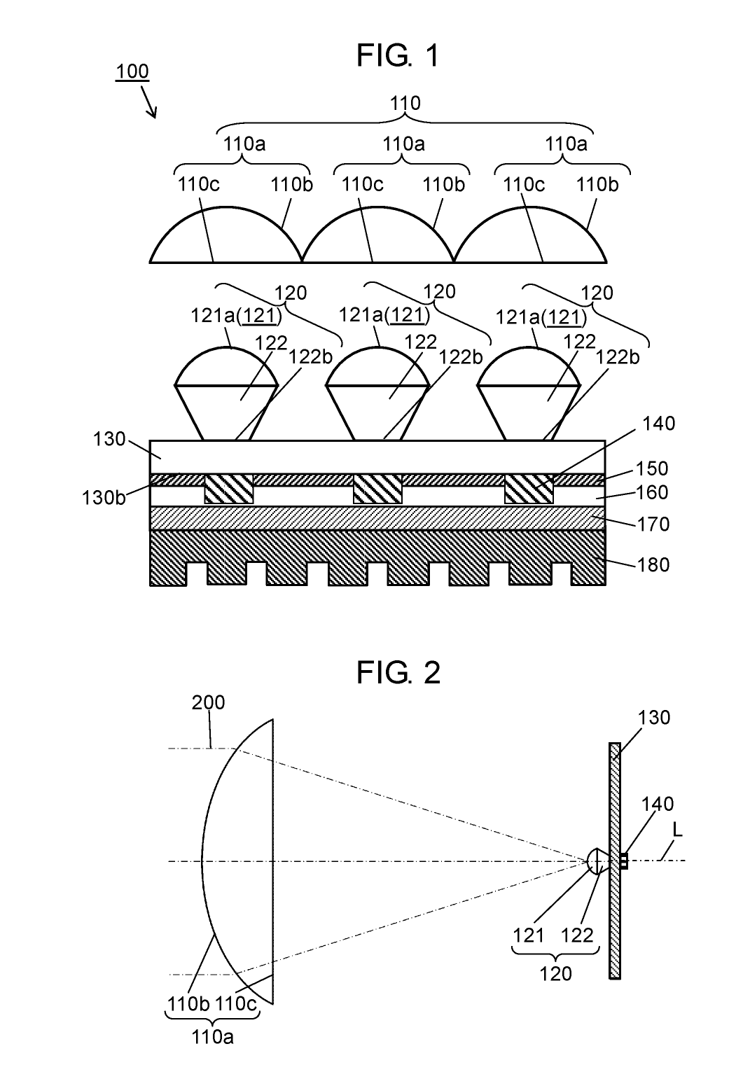

An overall configuration of photovoltaic cell 100 according to the present exemplary embodiment will be described below with reference to FIG. 1.

FIG. 1 is a schematic sectional view illustrating the configuration of the photovoltaic cell according to the present exemplary embodiment.

As illustrated in FIG. 1, photovoltaic cell 100 according to the present exemplary embodiment mainly includes light-receiving lens array 110, light guide element 120, glass substrate 130 having translucency, and photoelectric conversion element 140.

Light-receiving lens array 110 is configured by a plurality of light-receiving lenses 110a arranged in an array. Each of light-receiving lenses 110a has incidence surface 110b having a shape of a convex surface and emission surface 110c, for example. Light such as sunlight incident on light-receiving lens array 110 is condensed by a lens surface of each of light-receiving lenses 110a.

Photovoltaic cell 100 according to the present disclosure may include a sunlight tracking device (not illustrated) at an incidence surface 110b side of light-receiving lens array 110. With this configuration, photovoltaic cell 100 is capable of allowing sunlight to be incident on light-receiving lenses 110a always in nearly parallel (which includes in parallel) with respect to optical axes L of light-receiving lenses 110a, regardless of the location of the sun. Consequently, high conversion efficiency can be maintained.

Each of light-receiving lenses 110a according to the present exemplary embodiment includes a lens made of an acrylic resin and having positive optical power, for example. The material of each of light-receiving lenses 110a is not limited to an acrylic resin, and other resin materials or glass may be used.

Light guide element 120 has convex lens 121 having incidence surface 121a which is a convex surface, and light guide part 122. Light guide element 120 is disposed at a predetermined position at an emission surface 110c side of each of light-receiving lenses 110a. In this case, a plurality of light guide elements 120 is arranged in an array so as to correspond to light-receiving lenses 110a arranged in an array. Convex lens 121 is illustrated as one example of a convex part.

Emission light emitted from emission surface 110c of each of light-receiving lenses 110a is incident on convex lens 121 forming the convex part of each of light guide elements 120. The incident light is condensed by convex lens 121 having a convex surface shape, and enters light guide part 122. Light guide element 120 according to the present disclosure includes convex lens 121 and light guide part 122, which are separately provided. However, they may be integrally formed.

Light guide element 120 and photoelectric conversion element 140 are mounted on glass substrate 130 at positions opposite each other across glass substrate 130. Glass substrate 130 is illustrated as one example of a substrate. Therefore, the substrate is not limited to a glass substrate. Any substrate may be used, so long as it has high transparency to sunlight. For example, the substrate may be made of a resin such as an acrylic resin.

Photoelectric conversion element 140 is made of one or more light-absorptive materials capable of absorbing sunlight. Specifically, photoelectric conversion element 140 has a multi-junction structure in which multiple types of pn junctions having different absorption wavelength bands are layered. In the present exemplary embodiment, a multi-junction photovoltaic cell including three layers of InGaP, GaAs, and GaInAsN is used to convert light having a wavelength in a range from 400 nm to 1300 nm into electric energy, for example. Specifically, photoelectric conversion element 140 according to the present exemplary embodiment has a photoelectric conversion wavelength band from a wavelength of 400 nm to a wavelength of 1300 nm. Photoelectric conversion element 140 is mounted at a position opposite light guide element 120 across glass substrate 130.

Photovoltaic cell 100 also includes water-repellant film 150, anisotropic conductive film 160, wiring board 170, and radiator plate 180 at an emission surface 130b side of glass substrate 130.

Next, an operation of photovoltaic cell 100 according to the present exemplary embodiment will be described.

Sunlight is condensed on photoelectric conversion element 140 through light-receiving lens 110a. Light-receiving lens 110a, light guide element 120, and photoelectric conversion element 140 are mounted as one set, and a plurality of sets is arranged in an array.

Various shapes including rectangle, circle, and polygon such as hexagon are considered as the shape of the light-receiving surface of light-receiving lens 110a viewed from the direction of optical axis L. However, a rectangular shape or polygonal shape by which light-receiving lenses can be arranged in an array without a space therebetween is preferable in a concentrating photovoltaic cell in which a power generation amount per unit area is the key.

Incidence surface 110b of light-receiving lens 110a is formed to have an aspherical shape, for example. The aspherical shape is determined to reduce an increase in size of a condensing spot due to aberration. With this, deterioration in power generation efficiency of photovoltaic cell 100 caused by aberration of light-receiving lenses 110a can be prevented.

As described above, photoelectric conversion element 140 converts optical energy of sunlight having a wavelength within the photoelectric conversion wavelength band into electric energy. Electric energy resulting from conversion by photoelectric conversion element 140 is extracted from wiring board 170 through anisotropic conductive film 160. Anisotropic conductive film 160 has insulating property in the planar direction and conductivity in the thickness direction. Thus, anisotropic conductive film 160 electrically connects electrodes of photoelectric conversion elements 140 with wirings of wiring board 170. Photovoltaic cell 100 condenses sunlight and converts sunlight. Therefore, the temperature of photovoltaic cell 100 is likely to rise. In view of this, radiator plate 180 is provided to keep photovoltaic cell 100 at an appropriate operating temperature.

Photovoltaic cell 100 according to the present exemplary embodiment is configured as described above.

A method of adhering photoelectric conversion element 140 to glass substrate 130 will be described below.

Firstly, water-repellant film 150 made of [(2-perfluorooctyl)ethyl]trimethoxysilane is applied to emission surface 130b of glass substrate 130. Thereafter, a predetermined position on the surface to which water-repellant film 150 is applied is irradiated with light having a wavelength of 450 nm. Water-repellant film 150 is made of a material which is changed to be hydrophilic with irradiation of light. Thus, water-repellant film 150 applied to emission surface 130b of glass substrate 130 is changed to be hydrophilic only in a spot region irradiated with light. The predetermined position indicates a position opposite emission surface 122b of light guide part 122 of light guide element 120 provided at an incidence surface 130a side of glass substrate 130. Although not described, light guide element 120 is adhered to glass substrate 130 in the manner same as that for photoelectric conversion element 140.

Next, a transparent adhesive such as a silicone adhesive is applied to water-repellant film 150 on emission surface 130b of glass substrate 130 in this state. In this case, the applied transparent adhesive is concentrated on the region, which has been changed to be hydrophilic, of water-repellant film 150.

Then, photoelectric conversion element 140 is disposed on the transparent adhesive to be adhered and fixed. With this, photoelectric conversion element 140 is mounted at the predetermined position opposite light guide element 120 across glass substrate 130.

[1-2. Light-Receiving Lens]

Light-receiving lens 110a will be described below with reference to FIG. 2.

FIG. 2 is a sectional view for describing an optical path of sunlight incident on the photovoltaic cell according to the present exemplary embodiment.

Generally, when photovoltaic cell 100 receives nearly parallel light 200 (including parallel light 200) such as sunlight from the perpendicular direction, aberration characteristic is enhanced by setting optical power of incidence surface 110b of light-receiving lens 110a to be higher than optical power of emission surface 110c.

However, when optical power of light-receiving lens 110a is increased, the thickness of light-receiving lens 110a also increases. In this case, the configuration in which the convex surface defining incidence surface 110b of light-receiving lens 110a is formed into a Fresnel shape to suppress an increase in thickness has been known as a known technique. However, when incidence surface 110b side of light-receiving lens 110a is formed into a Fresnel shape, vignetting of a light beam occurs due to cutout surface of Fresnel lens. As a result, loss of a light beam reaching photoelectric conversion element 140 occurs, whereby optical energy to be converted is reduced.

In view of this, light-receiving lens 110a according to the present exemplary embodiment is configured such that incidence surface 110b has a shape of aspherical convex surface with positive optical power and emission surface 110c has a Fresnel shape with positive optical power as illustrated in FIG. 2. In this case, emission surface 110c is formed to have a Fresnel shape with a plane substrate in which height of cutout surfaces is constant. With this, thickness of light-receiving lens 110a is reduced.

In light-receiving lens 110a according to the present exemplary embodiment, positive optical power of emission surface 110c is set higher than positive optical power of incidence surface 110b. This enables thinning of light-receiving lens 110a.

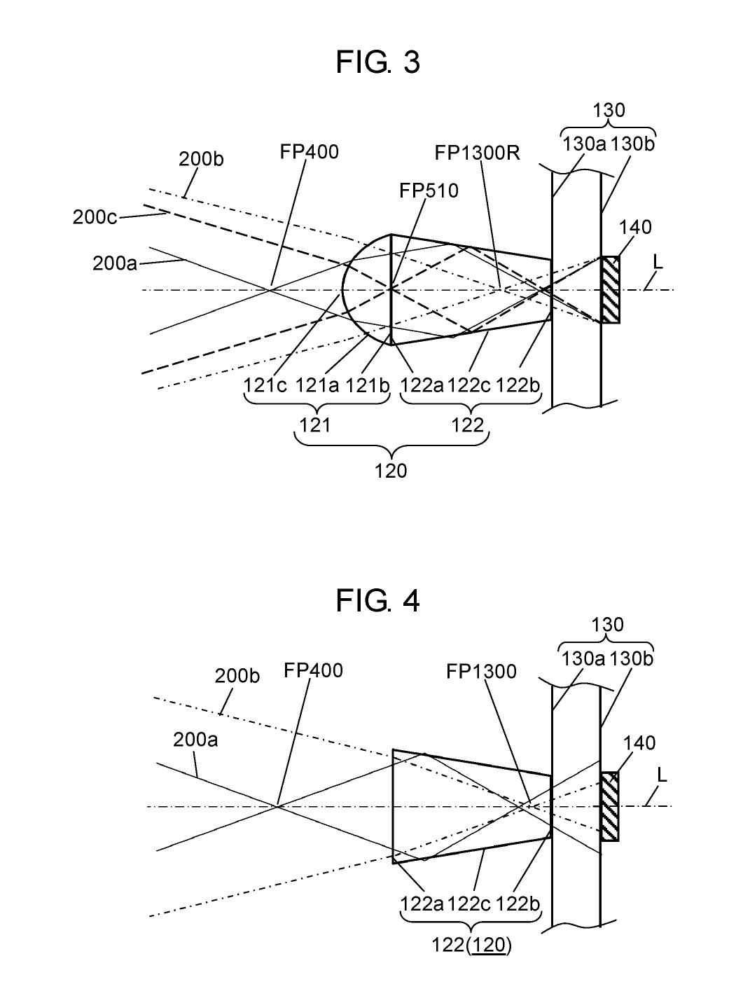

Specifically, as illustrated in FIG. 3, optical power (1/focal length) of light-receiving lens 110a is set such that a focal point for each wavelength due to axial chromatic aberration would be as stated below.

FIG. 3 is a sectional view illustrating optical paths of a short-wavelength light beam and a long-wavelength light beam which are incident on the light guide element according to the present exemplary embodiment. FIG. 3 illustrates, as one example, the case in which short-wavelength light beam 200a has a wavelength of 400 nm, medium-wavelength light beam 200c has a wavelength of 510 nm, and long-wavelength light beam 200b has a wavelength of 1300 nm, these wavelengths corresponding to the photoelectric conversion wavelength band of photoelectric conversion element 140.

Specifically, in the case of short-wavelength light beam 200a illustrated in FIG. 3, focal point FP400 (Focal Point) of light having a wavelength of 400 nm out of emission light from light-receiving lens 110a is set at a position closer to light-receiving lens 110a than apex 121c of convex lens 121 of light guide element 120. On the other hand, focal point FP 1300R of light having a wavelength of 1300 nm is set on the location where light guide part 122 of light guide element 120 is disposed, as indicated by long-wavelength light beam 200b in FIG. 3. In other words, it is set such that convex lens 121 constituting the convex part of light guide element 120 is located between focal point FP400 of short-wavelength light beam 200a and focal point FP1300R of long-wavelength light beam 200b on optical axis L.

Further, in the case of medium-wavelength light beam 200c illustrated in FIG. 3, focal point FP510 of light having a wavelength of 510 nm emitted from light-receiving lens 110a is set on incidence surface 122a of light guide part 122 of light guide element 120 or in vicinity thereof as described later.

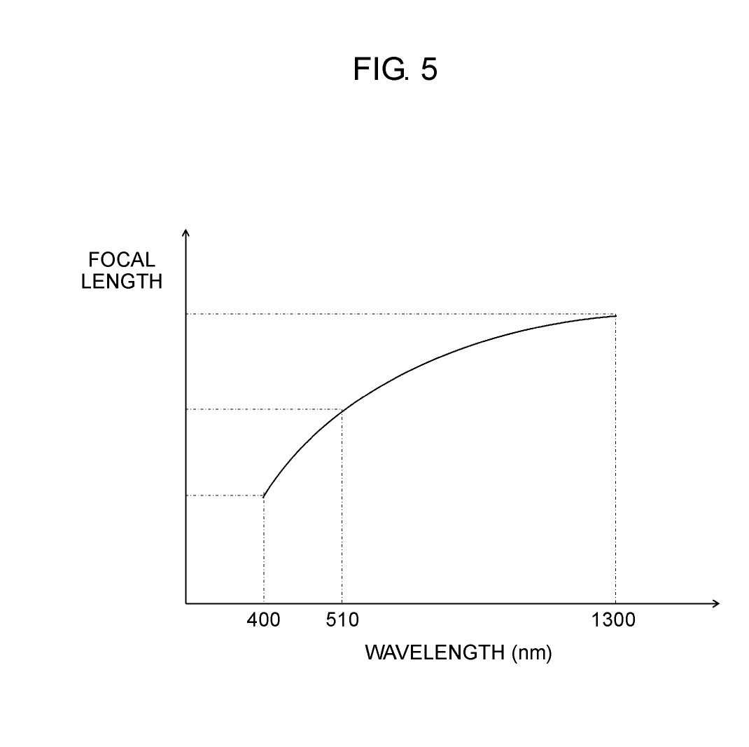

The relationship between wavelength of light incident on light-receiving lens 110a and focal length will be described here with reference to FIG. 5.

FIG. 5 is a graph illustrating an amount of change of focal length of light-receiving lens 110a when light having a wavelength from 400 nm to 1300 nm, which is the photoelectric conversion wavelength band of photoelectric conversion element 140, is incident. A horizontal axis indicates a wavelength of light incident on light-receiving lens 110a, and a vertical axis relatively indicates a focal length of incident light to a focal point of light-receiving lens 110a. A focal length is not uniquely determined, since it is changed according to design factors such as a shape or optical power of light-receiving lens 110a. Therefore, it is relatively illustrated.

In this case, light wavelength (wavelength at a center value of an amount of change of focal distance) located on a middle between a focal length of light-receiving lens 110a upon incidence of light having a wavelength of 400 nm and a focal length of light-receiving lens 110a upon incidence of light having a wavelength of 1300 nm corresponds to 510 nm as illustrated in FIG. 5.

In view of this, in the present exemplary embodiment, light guide part 122 is disposed such that focal point FP510 of light-receiving lens 110a upon incidence of light having a wavelength of 510 nm, which light is medium-wavelength light beam 200c, is located on incidence surface 122a of light guide part 122 or in the vicinity thereof as illustrated in FIG. 3. Specifically, light guide part 122 is disposed such that the distance from focal point FP400 of light having a wavelength of 400 nm to the position of incidence surface 122a of light guide part 122 and the distance from the position of incidence surface 122a of light guide part 122 to focal point FP1300R of light having a wavelength of 1300 nm are approximately equal to each other. Then, light-receiving lens 110a having the above focal point with respect to each wavelength is designed. This configuration suppresses an increase in size of the condensing spot on the photoelectric conversion element at the short-wavelength side and long-wavelength side caused by axial chromatic aberration of light-receiving lens 110a. Consequently, light loss of sunlight reaching photoelectric conversion element 140 from light-receiving lens 110a at the entire received wavelength can be prevented. In addition, light having a wavelength within the photoelectric conversion wavelength band of photoelectric conversion element 140 can be efficiently made incident on photoelectric conversion element 140 without light loss. This results in implementing photovoltaic cell 100 having high light use efficiency.

With light-receiving lens 110a of the present exemplary embodiment, aberration at the short-wavelength end, long-wavelength end, and their neighborhood within the received wavelength band of photoelectric conversion element 140 can satisfactorily be suppressed. Furthermore, increase in thickness of light-receiving lens 110a can be suppressed by reducing optical power of incidence surface 110b. Thus, downsizing and weight reduction of photovoltaic cell 100 can be implemented.

With the configuration in which incidence surface 110b of light-receiving lens 110a is formed into a convex surface, vignetting of incident sunlight can be prevented, whereby sunlight can effectively be condensed. In addition, with the configuration in which emission surface 110c of light-receiving lens 110a is formed into a Fresnel shape, a focal length to incident light can further be decreased. Accordingly, photovoltaic cell 100 can be downsized.

[1-3. Light Guide Element]

Light guide element 120 will be described below with reference to FIG. 3.

As illustrated in FIG. 3, light guide element 120 according to the present exemplary embodiment is disposed to face photoelectric conversion element 140 across glass substrate 130 constituting the substrate. Light guide element 120 is disposed at an emission surface 130b side of glass substrate 130, while photoelectric conversion element 140 is disposed to be adhered to incidence surface 130a side of glass substrate 130.

Light guide element 120 has convex lens 121 constituting the convex part and light guide part 122. Emission surface 121b of convex lens 121 and incidence surface 122a of light guide part 122 are in close contact with each other. Convex lens 121 has a shape of a convex surface having positive optical power on incidence surface 121a, and a flat shape on emission surface 121b. Convex lens 121 guides emission light, which is incident on incidence surface 121a and emitted from emission surface 121b, to light guide part 122.

Light guide part 122 is composed of a rod integrator, for example. The cross-sectional surface (hereinafter referred to as longitudinal section) of light guide part 122 parallel to optical axis L is formed into a tapered shape from incidence surface 122a side toward emission surface 122b side. With this, light incident on light guide part 122 can effectively be emitted to photoelectric conversion element 140.

In this case, an area (corresponding to the maximum cross-sectional area) of emission surface 121b of convex lens 121 is equal to an area (corresponding to the maximum cross-sectional area) of incidence surface 122a of light guide part 122. This can allow light incident on convex lens 121 to be reliably incident on incidence surface 122a of light guide part 122.

The cross-sectional surface (hereinafter referred to as transverse section) perpendicular (orthogonal) to optical axis L of convex lens 121 and light guide part 122 is formed into a shape of square according to the shape of light-receiving lens 110a, for example. Further, light guide part 122 is formed such that an area of incidence surface 122a is larger than an area of emission surface 122b. In other words, the longitudinal section from incidence surface 122a to emission surface 122b of light guide part 122 is formed into a tapered shape. Light guide part 122 is not limited to have the shape in which the area of the transverse section is gradually reduced as illustrated in FIG. 3. Other shapes may be employed, so long as the shape satisfies the condition in which the area of incidence surface 122a is larger than the area of emission surface 122b of light guide part 122. For example, the longitudinal section of light guide part 122 is formed such that a line drawn from incidence surface 122a to emission surface 122b is a curved line such as a parabola.

Optical paths of sunlight condensed by light-receiving lens 110a in photovoltaic cell 100 according to the present exemplary embodiment will be described below with reference to FIGS. 3 and 4.

FIG. 4 is a sectional view illustrating optical paths of a short-wavelength light beam and a long-wavelength light beam which are incident on a light guide element including only a light guide part. FIG. 4 is a drawing for comparison to optical paths of the light guide element having the convex part according to the present exemplary embodiment. Specifically, FIG. 4 illustrates optical paths of sunlight when light guide element 120 including only light guide part 122 is disposed in the dimensional relation same as in FIG. 3.

As described above, short-wavelength light beam 200a illustrated in FIGS. 3 and 4 indicates an optical path of sunlight which is condensed by light-receiving lens 110a and has a wavelength of 400 nm. Long-wavelength light beam 200b indicates an optical path of sunlight which is condensed by light-receiving lens 110a and has a wavelength of 1300 nm.

Specifically, as illustrated in FIG. 3, short-wavelength light beam 200a condensed by light-receiving lens 110a is condensed on focal point FP400 on optical axis L located anterior to apex 121c of incidence surface 121a of convex lens 121 (at the side close to light-receiving lens 110a) due to axial chromatic aberration of light-receiving lens 110a. After being condensed on focal point FP400, short-wavelength light beam 200a enters convex lens 121 having condensing function from incidence surface 121a, and passes therethrough, while diverging. At that time, short-wavelength light beam 200a enters light guide part 122 with its divergence angle being suppressed by convex lens 121 of light guide element 120. Short-wavelength light beam 200a incident on light guide part 122 enters glass substrate 130 from incidence surface 130a, while being totally reflected on tapered side face 122c of light guide part 122. Short-wavelength light beam 200a incident on glass substrate 130 enters photoelectric conversion element 140 from emission surface 130b of glass substrate 130. At that time, light-receiving lens 110a, light guide element 120, and glass substrate 130 are disposed on predetermined positions in order that short-wavelength light beam 200a is reliably incident on the entire surface of photoelectric conversion element 140. Thus, photoelectric conversion element 140 can efficiently convert short-wavelength light beam 200a into electric energy.

Long-wavelength light beam 200b illustrated in FIG. 3 is incident on light guide part 122 with its focal point being adjusted by convex lens 121 of light guide element 120. Long-wavelength light beam 200b incident on light guide part 122 is condensed on focal point FP1300R on optical axis L. After being condensed on focal point FP1300R, long-wavelength light beam 200b enters glass substrate 130 from incidence surface 130a, while diverging. Long-wavelength light beam 200b incident on glass substrate 130 is incident on the entire surface of photoelectric conversion element 140 from emission surface 130b of glass substrate 130. Specifically, long-wavelength light beam 200b is emitted such that focal point FP1300R is adjusted by convex lens 121 and its divergence angle matches the entire surface of photoelectric conversion element 140. Thus, photoelectric conversion element 140 can efficiently convert long-wavelength light beam 200b into electric energy.

On the other hand, when light guide element 120 does not have convex lens 121 as illustrated in FIG. 4, short-wavelength light beam 200a emitted from light-receiving lens 110a is condensed on focal point FP400 on optical axis L. Focal point FP400 in FIG. 4 is the same as focal point FP400 in FIG. 3, since the dimensional relation is same between FIG. 3 and FIG. 4.

Light condensed on focal point FP400 is directly incident on light guide part 122 from incidence surface 122a, while diverging. Short-wavelength light beam 200a incident on light guide part 122 passes through glass substrate 130, and enters photoelectric conversion element 140, while being totally reflected on side face 122c of light guide part 122. In this case, a part of short-wavelength light beam 200a cannot enter photoelectric conversion element 140 as illustrated in FIG. 4. Therefore, light use efficiency of photovoltaic cell 100 is deteriorated, when light guide element 120 does not have convex lens 121.

Long-wavelength light beam 200b illustrated in FIG. 4 directly enters light guide part 122 from incidence surface 122a. Long-wavelength light beam 200b incident on light guide part 122 is condensed on focal point FP1300 of light-receiving lens 110a on optical axis L. In this case, focal point FP1300 is closer to photoelectric conversion element 140 side, compared to focal point FP 1300R illustrated in FIG. 3. Therefore, long-wavelength light beam 200b condensed on focal point FP1300 then passes through glass substrate 130 and is incident on a part of the surface of photoelectric conversion element 140, while diverging. At that time, resistance of a part of photoelectric conversion element 140 which is not irradiated with light increases. Therefore, conversion efficiency of photoelectric conversion element 140 is reduced.

The configuration in FIG. 4 is capable of allowing light to be appropriately incident on photoelectric conversion element 140 according to the position where light-receiving lens 110a is placed or by increasing optical power. However, this configuration might entail increase in size of photovoltaic cell 100.

Light guide element 120 according to the present exemplary embodiment includes convex lens 121 and light guide part 122. Emission surface 121b of convex lens 121 is disposed to be in close contact with incidence surface 122a of light guide part 122. With this configuration, light having a wavelength within the photoelectric conversion wavelength band of photoelectric conversion element 140 can be effectively emitted on the entire surface of photoelectric conversion element 140. Consequently, compact and thin photovoltaic cell 100 having high efficiency can be implemented without deteriorating light use efficiency.

[2. Effect]

As described above, photovoltaic cell 100 according to the present exemplary embodiment includes: light-receiving lens 110a having condensing function; light guide element 120 disposed at an emission surface 110c side of light-receiving lens 110a ; glass substrate 130 mounted to be in contact with emission surface 122b of light guide element 120; and photoelectric conversion element 140 which is disposed at a position opposite light guide element 120 and on which light emitted from glass substrate 130 is incident. Light-receiving lens 110a is configured such that incidence surface 110b is a convex surface and emission surface 110c is formed into a Fresnel shape having positive optical power.

With this configuration, vignetting on incidence surface 110b of light-receiving lens 110a is suppressed, whereby incident sunlight having a wavelength within the photoelectric conversion wavelength band can efficiently be guided to photoelectric conversion element 140. Consequently, deterioration in light use efficiency can be prevented.

### Other Exemplary Embodiments

As presented above, the exemplary embodiment has been described as an example of the technique described in the present application. However, the technique in the present disclosure is not limited to these, and can be applied to embodiments in which various changes, replacements, additions, omissions, or the like are made. Moreover, constituent elements described in the above exemplary embodiment can be combined to provide a new embodiment.

Other exemplary embodiments will be illustrated below.

Specifically, the present exemplary embodiment describes that the area of emission surface 121b of convex lens 121 is equal to the area of incidence surface 122a of light guide part 122. However, the configuration is not limited thereto. For example, the area of emission surface 121b of convex lens 121 may be set smaller than the area of incidence surface 122a of light guide part 122.

Specifically, with the configuration of photovoltaic cell 100 including a sunlight tracking device to allow sunlight to be incident nearly perpendicularly at all times, sunlight can always be disposed on optical axis L. With this, the cross-sectional area of light flux incident on convex lens 121 can always be made smaller than the area of incidence surface 122a of light guide part 122 due to condensing with light-receiving lens 110a. According to this, the area of emission surface 121b of convex lens 121 can be set smaller than the area of incidence surface 122a of light guide part 122.

The present exemplary embodiment describes that light guide element 120 includes convex lens 121 and light guide part 122 which are separately provided. However, the configuration is not limited thereto. For example, convex lens 121 and light guide part 122 may be integrally formed to constitute light guide element 120. With this, a combining step, e.g., an adhesion step, may be eliminated, whereby light guide element 120 can efficiently be obtained.

The present exemplary embodiment describes that the convex part of light guide element 120 is composed of convex lens 121 having a convex surface. However, the configuration is not limited thereto. For example, the convex part may have a Fresnel shape having positive optical power. This enables further thinning.

Note that the above-described embodiments have been described to exemplify the technique according to the present disclosure, and therefore, various modifications, replacements, additions, and omissions may be made within the scope of the claims and the scope of the equivalents thereof.

What is claimed is:

1. A photovoltaic cell comprising:
a light-receiving lens having condensing function;
a light guide element disposed at an emission surface side of the light-receiving lens;
a translucent substrate mounted to be in contact with an emission surface of the light guide element; and
a photoelectric conversion element which is disposed at a position opposite the light guide element and on which light emitted from the substrate is incident,
wherein the light-receiving lens is configured such that an incidence surface is a convex surface and an emission surface is formed into a Fresnel shape having positive optical power.

2. The photovoltaic cell according to claim 1, wherein a focal point of the light-receiving lens at a short-wavelength end of a photoelectric conversion wavelength band of the photoelectric conversion element is located closer to the light-receiving lens side than an incidence surface of the light guide element.

3. The photovoltaic cell according to claim 1, wherein a focal point of the light-receiving lens at a long-wavelength end of a photoelectric conversion wavelength band of the photoelectric conversion element is located closer to an emission surface side than an incidence surface of the light guide element.

4. The photovoltaic cell according to claim 1, wherein the light guide element includes a convex part including a convex surface, and a light guide part having an incidence surface at an emission surface side of the convex part.

5. The photovoltaic cell according to claim 1, wherein an incidence surface of the light guide element is located between a focal point of the light-receiving lens at a short-wavelength end of a photoelectric conversion wavelength band of the photoelectric conversion element and a focal point of the light-receiving lens at a long-wavelength end of the photoelectric conversion wavelength band.

6. The photovoltaic cell according to claim 1, wherein a focal point of wavelength, within a photoelectric conversion wavelength band of the photoelectric conversion element, at a center value of an amount of change of focal length of the light-receiving lens is located on an incidence surface of the light guide element.

7. The photovoltaic cell according to claim 1, wherein the light guide element includes a lens at an incidence surface side.
